(19) United States
(12) Patent Application Publication
(10) Pub. No.: US 2025/0110156 A1
(43) Pub. Date: Apr. 3, 2025

(54) MAGNETIC SENSOR AND CURRENT SENSOR

(71) Applicant: Asahi Kasei Microdevices Corporation, Tokyo (JP)

(72) Inventors: Saki USHIDA, Tokyo (JP); Masato INOUE, Tokyo (JP)

(21) Appl. No.: 18/900,832

(22) Filed: Sep. 29, 2024

(30) Foreign Application Priority Data
Oct. 2, 2023 (JP) 2023-171132
Sep. 10, 2024 (JP) 2024-156692

(51) Int. Cl. G01R 15/20; G01R 19/00

(52) U.S. Cl. CPC G01R 15/205; G01R 19/0092

(57) ABSTRACT

A magnetic sensor 50 includes a first magneto-electric conversion unit 50a including a resistive side Ra, a resistive side Rb, a resistive side Rc, and a resistive side Rd, each formed by connecting a plurality of magnetoresistive elements 51 in series, wherein the magnetic sensing directions of a resistive side Ra and a resistive side Rd are identical to each other, magnetic sensing directions of the resistive side Rb and the resistive side Rc are identical to each other and opposite to the magnetic sensing directions of the resistive side Ra and the resistive side Rd, the resistive side Ra and the resistive side Rb are connected in series, the resistive side Rc and the resistive side Rd are connected in series and are connected in parallel to the resistive side Ra and the resistive side Rb to be assembled into a Wheatstone bridge circuit.

The contents of the following patent application(s) are incorporated herein by reference:
NO. 2023-171132 filed in JP on Oct. 2, 2023
NO. 2024-156692 filed in JP on Sep. 10, 2024

### BACKGROUND

### 1. Technical Field

The present invention relates to a magnetic sensor and a current sensor.

### 2. Related Art

A magnetic sensor is known, which includes a Wheatstone bridge circuit constituting of four resistive sides each including a magnetoresistive element (TMR) and detects a magnetic field intensity by inputting drive voltage from one pair of power supply nodes and obtaining a differential voltage from one pair of output nodes (see Patent Document 1 and 2). In a magnetic sensor with such a configuration, connecting a plurality of TMRs in series to constitute each resistive side can improve a DC voltage resistance and an ESD voltage resistance of the magnetic sensor. However, there is a concern that, as a result of a chip area (equal to a magneto-sensitive portion area) increasing, in other words, a closed loop formed by the four resistive sides increasing, and a large number of magnetic fluxes passing through the inside of the closed loop, not only an induced electromotive force is generated, resulting in a di/dt noise, but also a common-mode signal is generated due to a magnetic field distribution on the magneto-sensitive portion, resulting in a differential amplification noise.
Patent Document 1: International Publication No. 2015/107949
Patent Document 2: Specification of U.S. Patent Application Publication No. 2020/0018780

### BRIEF DESCRIPTION OF THE DRAWINGS

FIG. 1A illustrates an internal configuration of a current sensor according to the present embodiment in a top view.

FIG. 1B illustrates the internal configuration of the current sensor according to the present embodiment in a side view.

FIG. 2 illustrates a circuit configuration of a magnetic sensor (a magneto-electric conversion unit).

FIG. 3 illustrates a side view of a configuration of a magnetoresistive element.

FIG. 4A illustrates an example of an arrangement of a magnetic sensor that detects a horizontal magnetic field.

FIG. 4B illustrates a circuit configuration of the first magneto-electric conversion unit in FIG. 4A and a magnetic field detection direction of the magnetoresistive element.

FIG. 4C illustrates a circuit configuration of the second magneto-electric conversion unit in FIG. 4A and a magnetic field detection direction of the magnetoresistive element.

FIG. 5A illustrates an example of an arrangement of a magnetic sensor that detects a perpendicular magnetic field.

FIG. 5B illustrates a circuit configuration of a first magneto-electric conversion unit in FIG. 5A and a magnetic field detection direction of a magnetoresistive element.

FIG. 5C illustrates a circuit configuration of a second magneto-electric conversion unit in FIG. 5A and a magnetic field detection direction of a magnetoresistive element.

FIG. 6A illustrates a principle of generation of di/dt noise resulting from an induced electromotive force.

FIG. 6B illustrates a principle of suppressing the di/dt noise by twisting the wiring line.

FIG. 7A illustrates a planar array of a plurality of magnetoresistive elements.

FIG. 7B illustrates a three-dimensional array of a plurality of magnetoresistive elements.

FIG. 8A illustrates an array of unit regions in the first magneto-electric conversion unit.

FIG. 8B illustrates an array of unit regions in the second magneto-electric conversion unit.

FIG. 9 illustrates a magnetic field intensity relative to a position on the conductor and a common mode voltage output from the magneto-electric conversion unit.

FIG. 10 illustrates a common mode voltage output from the magneto-electric conversion unit relative to the ratio of the width of the magneto-electric conversion unit to the width of the conductor.

FIG. 11A illustrates a state of a lead frame forming process in a manufacturing flow of the current sensor.

FIG. 11B illustrates a state of a die bonding process in the manufacturing flow of the current sensor.

FIG. 11C illustrates a state of a wire bonding process in the manufacturing flow of the current sensor.

FIG. 11D illustrates a state of a molding process in the manufacturing flow of the current sensor.

FIG. 12A illustrates a top view of an internal configuration of a current sensor according to a modified example.

FIG. 12B illustrates a side view of the internal configuration of the current sensor according to the modified example.

FIG. 13A illustrates a state of a lead frame forming process in the manufacturing flow of the current sensor according to the modified example.

FIG. 13B illustrates a state of a magnetic sensor installation process in the manufacturing flow of the current sensor according to the modified example.

FIG. 13C illustrates a state of a wire bonding process in the manufacturing flow of the current sensor according to the modified example.

FIG. 13D illustrates a state of a molding process in the manufacturing flow of the current sensor according to the modified example.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

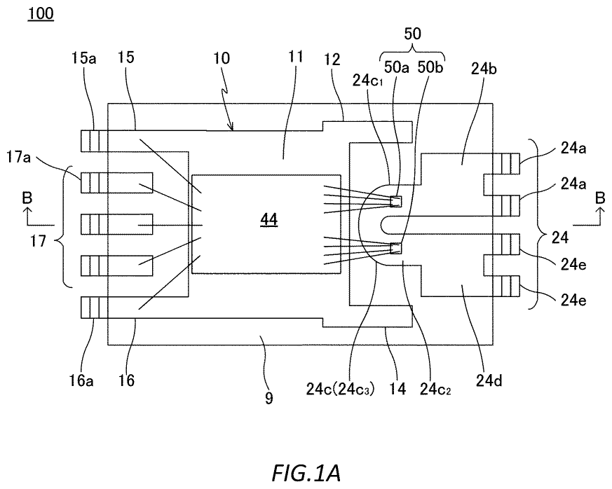

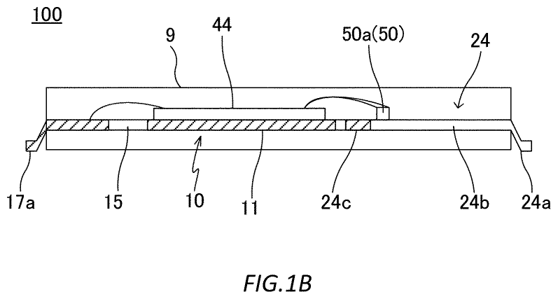

FIG. 1A and FIG. 1B illustrate the internal configuration of the current sensor 100 according to the present embodiment in the top view and the side view, respectively, where the package 9 is omitted. Herein, FIG. 1B illustrates a cross-sectional structure of the current sensor 100 with respect to a reference line BB in FIG. 1A. It should be noted that an up-and-down direction in FIG. 1A is referred to as a longitudinal direction, a left-and-right direction in FIG. 1A and FIG. 1B is referred to as a lateral direction, and an up-and-down direction in FIG. 1B is referred to as a height direction. The current sensor 100 is a sensor for measuring the amount of currents by detecting, using a magnetic sensor 50, the magnetic field generated around the conductor 24 through which a to-be-measured current flows, and in particular can suppress di/dt noise due to an induced electromotive force and/or a differential amplification noise resulting from the spread of magnetic field distribution. The current sensor 100 includes a package 9, a base 10, a plurality of device terminals 17, a conductor 24, a magnetic sensor 50, and a signal processing device 44.

The package 9 is a member that protects each portion constituting the current sensor 100 by encapsulating it inside except for two device terminals 15, 16, a plurality of device terminals 17, and each terminal portion of the conductor 24 included in a base 10 described below. The package 9 is formed of an encapsulating resin with a good insulating property such as epoxy, for example, that is shaped into a flat cuboid by molding.

The base 10 is a board-like member that supports the signal processing device 44. The base 10 is formed of, for example, metal with high thermal conductivity into a board, especially in order to release heat generated by the signal processing device 44. The base 10 has a body 11, protruding portions 12, 14, and device terminals 15, 16.

The body 11 is a portion that supports the signal processing device 44. The body 11 has an approximately rectangular shape with a sufficient size for supporting the signal processing device 44 in a planar view, as an example.

The protruding portions 12, 14 extend rightward from one end (that is, the upper end in FIG. 1A) and the other end (that is, the lower end in FIG. 1A), respectively, of one side of the body 11 in the lateral direction (that is, the right side in FIG. 1A). When the magnetic sensor 50 is arranged around the conductor 24, an insulating member can be fixed between the protruding portions 12, 14 and the magnetic sensor 50 can be arranged on the insulating member.

The device terminals 15, 16 are portions that output, to an external device, a detection result of the to-be-measured current output from the signal processing device 44. The device terminals 15, 16 extend leftward from one end (that is, the upper end in FIG. 1A) and the other end (that is, the lower end in FIG. 1A) of the other side (that is, the left side in FIG. 1A) of the body 11 in a lateral direction. The device terminals 15, 16 form terminal portions 15a, 16a on each of their end portions by bending their end portions downward and further bending their tips to be positioned horizontally by a bending process.

The base 10 is encapsulated within the package 9 with the terminal portions 15a, 16a of the device terminals 15, 16 protruding from the side surface of the package 9.

As with the device terminals 15, 16, the plurality of device terminals 17 are secondary conductors that output, to an external device, a detection result of the to-be-measured current output from the signal processing device 44. Furthermore, as with the device terminals 15, 16, the plurality of device terminals 17 are used for providing a power supply or an operational parameter to the signal processing device 44. In the present embodiment, as an example, three device terminals 17 are arrayed at a regular interval between the device terminals 15, 16 of the base 10, with their longitudinal sides being oriented in the lateral direction. The device terminal 17 is formed of a metal that is shaped into a rectangular board, and similar to the device terminals 15, 16, forms a terminal portion 17a on their end portions by bending their end portions downward and further bending their tips to be positioned horizontally by a bending process.

The conductor 24 is a primary conductor that forms a current path in which the to-be-measured current is flowing. In the present embodiment, the conductor 24 has an approximately U-shape that enters into the package 9 from a current terminal 24a provided on one side (that is, the upper side of FIG. 1A) of the right side of the package 9 and returns to the right side by passing through an inside of the package 9, and leading to a current terminal 24e provided on the other side (that is, the lower side of FIG. 1A) of the right side. The conductor 24 is formed of a metal. The conductor 24 includes current terminals (also simply referred to as a terminal portion) 24a, 24e, barrel portions 24b, 24d, and a curved portion 24c.

Each of the terminal portions 24a, 24e forms a terminal for inputting a current, by protruding from the right side of the package 9, bending their end portion downward by a bending process, and further bending the tip to be positioned horizontally.

The barrel portions 24b, 24d are portions connecting the terminal portions 24a, 24e to the curved portion 24c. As an example, the barrel portions 24b, 24d are formed into a rectangular shape, are connected to the two terminal portions 24a, 24e on the right side, which are separated, and are connected to the two arms 24c₁, 24c₂ of the curved portion 24c on the left side.

The curved portion 24c has two arms 24c₁, 24c₂ and a joining portion 24c₃ that joins these two arms 24c₁, 24c₂. The two arms 24c₁, 24c₂ may extend on the same side with respect to the joining portion 24c₃. Herein, the direction in which the width of the arm 24c₁ expands (identical to the longitudinal direction in FIG. 1A) is also referred to as a width direction and the direction in which the arm 24c₁ extends with respect to the joining portion 24c₃ is also referred to as an extension direction (identical to the lateral direction in FIG. 1A). In other words, the width direction and the extension direction intersect. The two arms 24c₁, 24c₂ have widths in the longitudinal direction that are smaller than those of the barrel portions 24b, 24d. In the curved portion 24c, the joining portion 24c₃ curves in an approximately arc shape, from both ends of which the two arms 24c₁, 24c₂, separated from each other in the width direction, extend in the lateral direction. It should be noted that the curved portion 24c may bend to have a rectangular U-shape. In the curved portion 24c, the to-be-measured current is input into one arm among the two arms 24c₁, 24c₂ and the to-be-measured current is output from the other arm via the joining portion 24c₃.

The conductor 24 has the curved portion 24c arranged between the protruding portions 12, 14 of the base 10, has the tips of the terminal portions 24a, 24e protruding from the right side of the package 9, and is encapsulated within the package 9.

The magnetic sensor 50 is a sensor which detects a magnetic field generated by the to-be-measured current flowing through the conductor 24. As an example, the magnetic sensor 50 includes two magneto-electric conversion units, that is, a first magneto-electric conversion unit 50a and a second magneto-electric conversion unit 50b, which are each configured to detect the magnetic field in the longitudinal direction generated around the conductor 24 (an example of the horizontal magnetic field). The first magneto-electric conversion unit 50a and the second magneto-electric conversion unit 50b are arranged on the arms 24c₁, 24c₂ of the curved portion 24c of the conductor 24, respectively, and are connected in parallel. It should be noted that the magnetic sensor 50 may include only one of the first magneto-electric conversion unit 50a or the second magneto-electric conversion unit 50b.

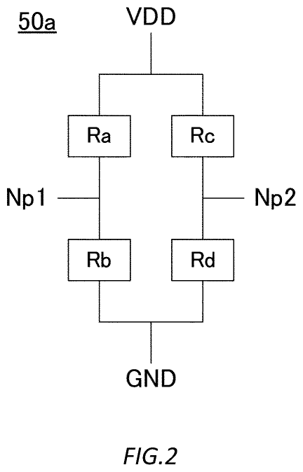

FIG. 2 illustrates a circuit configuration of the first magneto-electric conversion unit 50a of the magnetic sensor 50. The first magneto-electric conversion unit 50a includes four resistive sides Ra to Rd. Herein, the four resistive sides Ra to Rd are assembled into a Wheatstone bridge circuit. In other words, the resistive side Ra and the resistive side Rb are connected in series to form the output terminal Np1 between them, the resistive side Rc and the resistive side Rd are connected in series to form the output terminal Np2 between them, the resistive side Ra and the resistive side Rb and the resistive side Rc and the resistive side Rd are connected in parallel to form a power supply terminal VDD between the resistive side Ra and the resistive side Rc as well as to form the ground terminal GND between the resistive side Rb and the resistive side Rd.

It should be noted that, in the current sensor 100 according to the present embodiment, the magnetic field detection direction from the resistive side Ra to the resistive side Rd (that is, the magnetic sensing direction) is parallel to the width direction (the longitudinal direction in FIG. 1A). The magnetic field detection directions of the resistive side Ra and the resistive side Rd are identical to each other and, in the present example, is upward (or downward) in the longitudinal direction in FIG. 1A. The magnetic field detection directions of the resistive side Rb and the resistive side Rc are identical to each other and, in the present example, is downward (or upward) in the longitudinal direction in FIG. 1A. The magnetic field detection direction of the resistive side Ra and the resistive side Rd is opposite to the magnetic field detection direction of the resistive side Rb and the resistive side Rc.

Each of the four resistive sides Ra to Rd is formed by, for example, connecting a plurality of magnetoresistive elements 51 (51a to 51d) in series. It should be noted that, as a magnetoresistive element, for example, a tunneling magnetoresistive element or a giant magnetoresistive element can be employed.

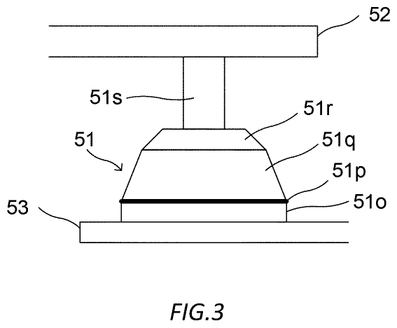

FIG. 3 shows a configuration of a magnetoresistive element 51 (51a to 51d) in a side view. The magnetoresistive element 51 is an element with a resistance value varying depending on application of a magnetic field, and has a fixed layer 51o, a tunnel layer 51p, a free layer 51q, and a cap layer 51r. The fixed layer 51o is a magnetic film whose direction of magnetization is fixed. The fixed layer 51o is magnetized such that its magnetization is oriented in a single-axis direction in a plane on which the magnetic film spreads (also referred to as a magneto-sensitive surface) or in a direction perpendicular to the magneto-sensitive surface. The direction of magnetization of the fixed layer 51o defines a magnetic field detection direction of the magnetoresistive element 51. The tunnel layer 51p is, for example, a non-magnetic insulating film with a thickness of several nanometers. The free layer 51q is a magnetic film whose direction of magnetization changes depending on an external magnetic field. It should be noted that, as the material of the magnetic film, an alloy including, for example, at least one of Co, Fe, B, Ni, or Si and more specifically cobalt iron (CoFe), cobalt iron boron (CoFeB), or nickel iron (NiFe) can be used. The fixed layer 51o, the tunnel layer 51p, and the free layer 51q are stacked to constitute a stacked body. Here, a current flows in the element in a stacked direction as a result of electrons moving from the fixed layer 51o to the free layer 51q or from the free layer 51q to the fixed layer 51o by tunneling through the tunnel layer 51p. The cap layer 51r is a member covering the stack from above and can be made of an alloy including at least one of, for example, Ta, Ru, Pt, Mn, Ir, Mg, Cu, Fe, Ni, Cr, Fe, Co, or Al, more specifically, platinum manganese (PtMn) or iridium manganese (IrMn). It should be noted that a region around the magnetoresistive element 51 is covered with an insulator (not shown), for example, silicon dioxide (SiO₂), silicon nitride (SiN), or the like.

When the external magnetic field is applied to the magnetoresistive element 51, due to a magnetoresistive effect (MR effect), the direction of magnetization of the free layer 51q changes depending on a direction and intensity of the magnetic field, that is, the direction of magnetization of the free layer 51q changes with respect to the direction of magnetization of the fixed layer 51o, so that the resistance value between the fixed layer 51o and the free layer 51q varies. Especially, when the direction of magnetization of the free layer 51q is the same as the direction of magnetization of the fixed layer 51o (the magnetizations of the two layers are parallel), the resistance value is small, and when the direction of magnetization of the free layer 51q is opposite to the direction of magnetization of the fixed layer 51o (the magnetizations of the two layers are antiparallel), the resistance value is high.

It should be noted that connecting a plurality of magnetoresistive elements 51 in series can improve a DC voltage resistance. Herein, by connecting the electrode piece 52 to the cap layer 51r via the electrode rod 51s and connecting the electrode piece 53 to the lower surface of the fixed layer 51o, the magnetoresistive element 51 can be connected to another magnetoresistive element 51 via these electrode pieces 52, 53. In other words, the plurality of magnetoresistive elements 51 can be arrayed in a plane. In addition, the plurality of magnetoresistive element 51 can be arrayed three-dimensionally by connecting the cap layer 51r of the magnetoresistive element 51 to the fixed layer 51o of another magnetoresistive element 51 via the electrode rod 51s.

At least a part of the first magneto-electric conversion unit 50a (for example, any one of a plurality of unit regions Ea₁ to Ea₄, Eb₁ to Eb₄, Ec₁ to Ec₄. and Ed₁ to Ed₄ included in the resistive sides Ra to Rd described below) is arranged on the arm 24c₁. When the to-be-measured current flows through the conductor 24 and generates a magnetic field around the conductor 24, a magnetic field in the longitudinal direction is applied to the resistive sides Ra to Rd (the magnetoresistive elements 51a to 51d included in them) of the first magneto-electric conversion unit 50a arranged on the arm 24c₁ of the conductor 24 and each resistance value varies. For example, the resistance values of the resistive sides Ra, Rd increase (or decrease) and the resistance values of the resistive sides Rb, Rc decrease (or increase), thereby disrupting the resistance balance of the resistive sides Ra to Rd. Herein, the magnetic field intensity can be detected by inputting the drive voltage into the power supply terminal VDD relative to the ground terminal GND and detecting the differential voltage output between the output terminals Np1, Np2.

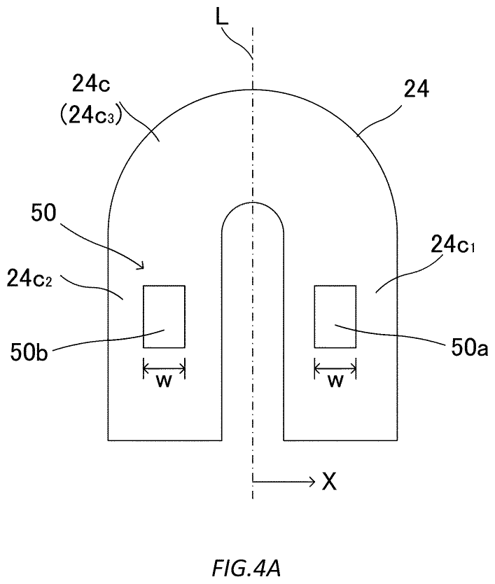

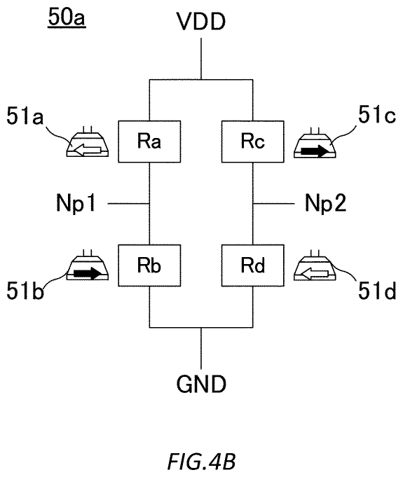

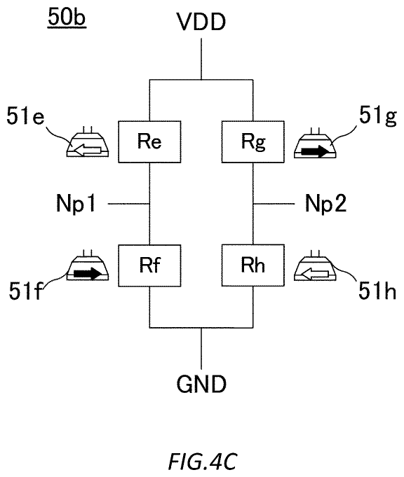

The second magneto-electric conversion unit 50b is configured similarly to the first magneto-electric conversion unit 50a. The first magneto-electric conversion unit 50a includes four resistive sides Re to Rh (see FIG. 4C). Herein, the four resistive sides Re to Rh are assembled into a Wheatstone bridge circuit. In other words, the resistive side Re and the resistive side Rf are connected in series to form the output terminal Np1 between them, the resistive side Rg and the resistive side Rh are connected in series to form the output terminal Np2 between them, the resistive side Re and the resistive side Rf and the resistive side Rg and the resistive side Rh are connected in parallel to form the power supply terminal VDD between the resistive side Re and the resistive side Rg as well as to form the ground terminal GND between the resistive side Rf and the resistive side Rh.

The magnetic field detection direction from the resistive side Re to the resistive side Rh (that is, the magnetic sensing direction) is parallel to the width direction (the longitudinal direction in FIG. 1A). The magnetic field detection directions of the resistive side Re and the resistive side Rh are identical to each other and, in the present example, are upward (or downward) in the longitudinal direction in FIG. 1A. The magnetic field detection directions of the resistive side Rf and the resistive side Rg are identical to each other and, in the present example, is downward (or upward) in the longitudinal direction in FIG. 1A. The magnetic field detection direction of the resistive side Re and the resistive side Rh is opposite to the magnetic field detection direction of the resistive side Rf and the resistive side Rg.

Each of the four resistive sides Re to Rh is formed by, for example, connecting the plurality of magnetoresistive elements 51 (51e to 51h) in series. It should be noted that, as a magnetoresistive element, for example, a tunneling magnetoresistive element or a giant magnetoresistive element can be employed.

At least a part of the second magneto-electric conversion unit 50b (for example, any one of a plurality of unit regions Ea₁ to Ea₄, Eb₁ to Eb₄, Ec₁ to Ec₄. and Ed₁ to Ed₄ included in the resistive sides Re to Rh described below) is arranged on the arm 24c₂. When the to-be-measured current flows through the conductor 24 and generates a magnetic field around the conductor 24, a magnetic field in the longitudinal direction is applied to the resistive sides Re to Rh (the magnetoresistive elements 51e to 51h included in them) of the second magneto-electric conversion unit 50b arranged on the arm 24c₂ of the conductor 24 and each resistance value varies. For example, the resistance values of the resistive sides Re, Rh increase (or decrease) and the resistance values of the resistive sides Rf, Rg decrease (or increase), leading to disruption of the resistance balance of the resistive sides Re to Rh. Herein, the magnetic field intensity can be detected by inputting the drive voltage into the power supply terminal VDD relative to the ground terminal GND and detecting the differential voltage output between the output terminals Np1, Np2.

It should be noted that, in the magnetic sensor 50, the second magneto-electric conversion unit 50b may be connected in parallel to the first magneto-electric conversion unit 50a. In other words, the respective ground terminals GND of the first magneto-electric conversion unit 50a and the second magneto-electric conversion unit 50b may be connected and the respective power supply terminals VDD may be connected. In addition, the first magneto-electric conversion unit 50a and the second magneto-electric conversion unit 50b may be configured independently of each other. The configuration of the first magneto-electric conversion unit 50a and the second magneto-electric conversion unit 50b of the magnetic sensor 50 will be further described below.

The first magneto-electric conversion unit 50a and the second magneto-electric conversion unit 50b of the magnetic sensor 50 are connected to the signal processing device 44 via wire bonding and output the voltage corresponding to the detected magnetic field intensity as the output signal to the signal processing device 44.

The signal processing device 44 is a device which processes the output signal of the magnetic sensor 50 to calculate an amount of the to-be-measured current flowing through the conductor 24. The signal processing device 44 may incorporate a memory, a sensitivity correction circuit, an offset correction circuit which corrects an offset of an output, an amplifying circuit which amplifies the output signal from the magnetic sensor 50, and a temperature correction circuit which corrects the output according to temperature. The signal processing device 44 is supported on the body 11 of the base 10 and is connected to the device terminals 15, 16 and three device terminals 17 of the base 10 via wire bonding. In this way, the signal processing device 44 outputs, via the device terminals 15, 16, 17, a calculation result of the amount of the to-be-measured current flowing through the conductor 24.

FIG. 4A illustrates an example of the arrangement of the magnetic sensor 50 (the first magneto-electric conversion unit 50a and the second magneto-electric conversion unit 50b). As described above, the first magneto-electric conversion unit 50a and the second magneto-electric conversion unit 50b can be arranged on the two arms 24c₁, 24c₂ of the conductor 24, respectively. The offset due to the disturbance magnetic field can be offset by calculating the difference in the output signal between the first magneto-electric conversion unit 50a and the second magneto-electric conversion unit 50b. The magnetic sensor 50 arranged at such a position is configured to detect a horizontal magnetic field parallel to an upper surface of the conductor 24 (in the present example, the magnetic field in the longitudinal direction in FIG. 1A). It should be noted that one of the first magneto-electric conversion unit 50a and the second magneto-electric conversion unit 50b may be arranged on the conductor 24 (the two arms 24c₁, 24c₂, the joining portion 24c₃, or the like).

FIG. 4B illustrates the magnetic field detection direction of the four resistive sides Ra to Rd (the magnetoresistive elements 51a to 51d included in them, respectively) included in the first magneto-electric conversion unit 50a in FIG. 4A. The magnetic field detection directions of the resistive side Ra (the magnetoresistive element 51a) and the resistive side Rd (the magnetoresistive element 51d) are the same, and in the present example, they are one direction that is a single-axis direction parallel to the upper surface of the conductor 24 (indicated by hollow arrows in the figure). The magnetic field detection directions of the resistive side Rb (the magnetoresistive element 51b) and the resistive side Rc (the magnetoresistive element 51c) are the same, and in the present example, they are each another single-axis direction parallel to the upper surface of the conductor 24 (indicated by filled arrows in the figure). The magnetic field detection directions of the resistive side Ra and the resistive side Rd are opposite to the magnetic field detection directions of the resistive side Rb and the resistive side Rc. In this way, the first magneto-electric conversion unit 50a can detect the horizontal magnetic field generated on the upper surface of the arm 24c₁ of the conductor 24.

FIG. 4C illustrates the magnetic field detection direction of the four resistive sides Re to Rh (the magnetoresistive elements 51e to 51h included in them, respectively) included in the second magneto-electric conversion unit 50b of FIG. 4A. The magnetic field detection directions of the resistive side Re (the magnetoresistive element 51e) and the resistive side Rh (the magnetoresistive element 51h) are the same, and in the present example, they are in one direction that is single-axis direction parallel to the upper surface of the conductor 24 (indicated by hollow arrows in the figure). The magnetic field detection directions of the resistive side Rf (the magnetoresistive element 51f) and the resistive side Rg (the magnetoresistive element 51g) are the same, and in the present example, they are each another single-axis direction parallel to the upper surface of the conductor 24 (indicated by filled arrows in the figure). The magnetic field detection direction of the resistive side Re and the resistive side Rh is opposite to the magnetic field detection direction of the resistive side Rf and the resistive side Rg. In this way, the second magneto-electric conversion unit 50b can detect the horizontal magnetic field generated on the upper surface of the arm 24c₂ of the conductor 24.

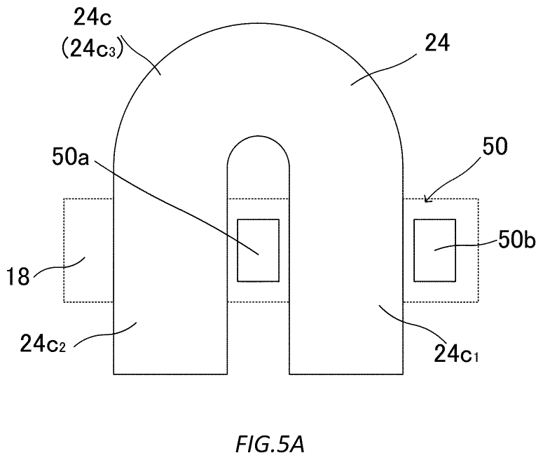

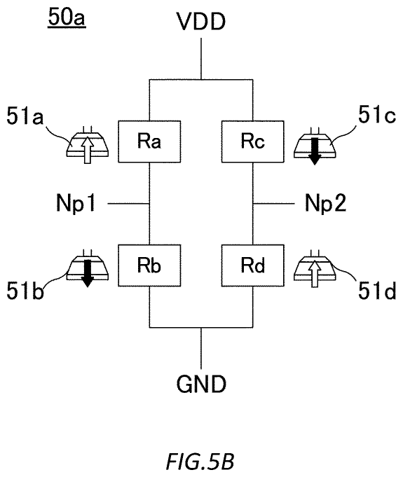

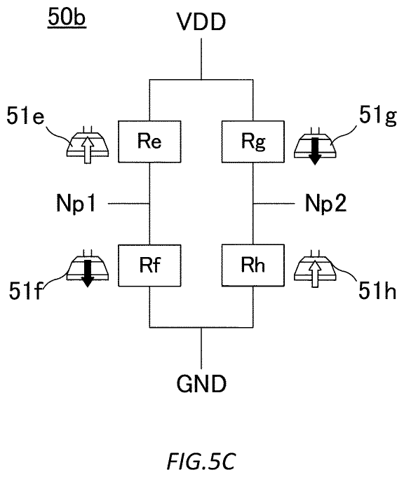

FIG. 5A illustrates another example of the arrangement of the magnetic sensor 50 (the first magneto-electric conversion unit 50a and the second magneto-electric conversion unit 50b). The first magneto-electric conversion unit 50a is arranged in the gap region surrounded by the curved portion 24c of the conductor 24. Furthermore, the second magneto-electric conversion unit 50b may be arranged in the vicinity of one of the two arms 24c₁, 24c₂ of the conductor 24 (the right side of the arm 24c₁ in the present example). In this way, the disturbance magnetic field can be canceled. The first magneto-electric conversion unit 50a and the second magneto-electric conversion unit 50b arranged in such a position are configured to detect the perpendicular magnetic field that is perpendicular to the upper surface the conductor 24 (in the case of the present example, the magnetic field in the height direction in FIG. 1A).

It should be noted that the first magneto-electric conversion unit 50a and the second magneto-electric conversion unit 50b can be arranged in the vicinity of the conductor 24 by placing an insulating member 18 (see FIG. 5A) between the protruding portions 12, 14 by attaching it on the lower surfaces of the protruding portions 12, 14 of the base 10, and supporting the first magneto-electric conversion unit 50a and the second magneto-electric conversion unit 50b on the insulating member 18. It should be noted that,
the insulating member 18 is made of a material with a high dielectric withstand voltage such as polyimide tape as an example and is formed into a film shape.

In addition, the curved portion 24c of the conductor 24 may be raised relative to the barrel portions 24b, 24d by providing a step in the height direction by a step process (for example, half-punching, etching, forming, coining, or the like). In this way, the bottom surface of the curved portion 24c is above the upper surface of the insulating member 18 attached to the bottom surfaces of the protruding portions 12, 14 of the base 10 and the primary conductor including the conductor 24 is separated from the insulating member 18 connected to the secondary conductor including the device terminals 15, 16, 17, resulting in a high dielectric withstand voltage between the primary conductor and the secondary conductor within the package 9.

FIG. 5B illustrates the magnetic field detection direction of the four resistive sides Ra to Rd (the magnetoresistive elements 51a to 51d included in them, respectively) included in the first magneto-electric conversion unit 50a in FIG. 5A. The magnetic field detection directions of the resistive side Ra (the magnetoresistive element 51a) and the resistive side Rd (the magnetoresistive element 51d) are the same, and in the present example, they are upward direction perpendicular to the upper surface of the conductor 24 (indicated by hollow arrows in the figure). The magnetic field detection directions of the resistive side Rb (the magnetoresistive element 51b) and the resistive side Rc (the magnetoresistive element 51c) are the same, and in the present example, they are downward directions perpendicular to the upper surface of the conductor 24 (indicated by filled arrows in the figure). The magnetic field detection directions of the resistive side Ra and the resistive side Rd are opposite to the magnetic field detection directions of the resistive side Rb and the resistive side Rc. In this way, the perpendicular magnetic field generated in the gap region of the conductor 24 can be detected by the first magneto-electric conversion unit 50a.

FIG. 5C illustrates the magnetic field detection direction of the four resistive sides Re to Rh (the magnetoresistive elements 51e to 51h included in them, respectively) included in the second magneto-electric conversion unit 50b of FIG. 5A. The magnetic field detection directions of the resistive side Re (the magnetoresistive element 51e) and the resistive side Rh (the magnetoresistive element 51h) are the same, and in the present example, they are upward directions perpendicular to the upper surface of the conductor 24 (indicated by hollow arrows in the figure). The magnetic field detection directions of the resistive side Rf (the magnetoresistive element 51f) and the resistive side Rg (the magnetoresistive element 51g) are the same, and in the present example, they are downward directions perpendicular to the upper surface of the conductor 24 (indicated by filled arrows in the figure). The magnetic field detection direction of the resistive side Re and the resistive side Rh is opposite to the magnetic field detection direction of the resistive side Rf and the resistive side Rg. In this way, the perpendicular magnetic field generated around the conductor 24 can be detected by the second magneto-electric conversion unit 50b.

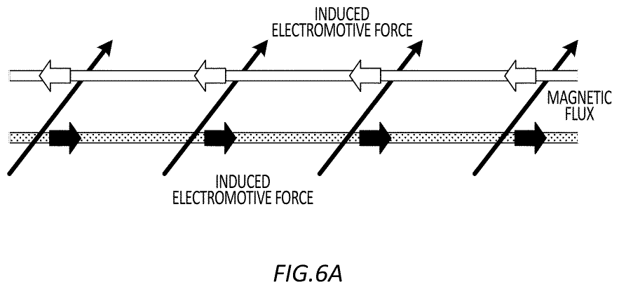

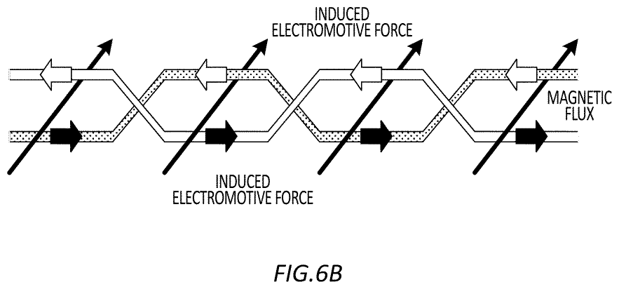

FIG. 6A shows a principle of generation of a di/dt noise caused by induced electromotive forces. When a magnetic field (magnetic flux density B) is applied to two wiring lines constituting the Wheatstone bridge circuit (that is, the closed loops) of the magnetic sensor 50 (the first magneto-electric conversion unit 50a and the second magneto-electric conversion unit 50b) and a magnetic flux (ϕ=BS, S is the area between the wiring lines) passes between the two wiring lines, an induced electromotive force (V=−dϕ/dt=−SdB/dt) is generated in the two wiring lines to offset the decrease or increase in the magnetic flux density (the magnetic field intensity B/μ, μ is a magnetic permeability). When the wiring lines are parallel, leftward induced electromotive forces (indicated by hollow arrows in the figure) applied to an upper wiring line and rightward induced electromotive forces (indicated by filled arrows in the figure) applied to a lower wiring line by respective magnetic fluxes penetrating between the wiring lines are added together, to generate a great induced electromotive force between the two wiring lines. As a result, a noise, the so-called di/dt noise, caused by the induced electromotive forces is superimposed on an output signal of the magnetic sensor.

FIG. 6B shows a principle of suppressing the di/dt noise. A plurality of partial loops with equal areas are formed in the closed loop by twisting the two wiring lines constituting the closed loop to form twisted wires. When the magnetic field (the magnetic flux density B) is applied to the two wiring lines, and a magnetic flux passes through each of the plurality of partial loops, induced electromotive forces are generated in the wiring lines constituting each of the partial loops such that the increase or decrease in the magnetic flux density is offset. In the case of a twisted wire, in each of the partial loops, a leftward induced electromotive force (indicated by a hollow arrow in the figure) is applied to the upper wiring line, and a rightward induced electromotive force (indicated by a filled arrow in the figure) is applied to the lower wiring line. However, in each of the two wiring lines, a direction of the induced electromotive force is changed for each of parts constituting the partial loops, so that an induced electromotive force applied to the entire wiring line is suppressed. It should be noted that directions of the induced electromotive forces generated in each of the loops are also referred to as polarities. Especially, when an even number of partial loops are formed, the induced electromotive force applied to the entire wiring line is offset. In this way, the di/dt noise can be offset or significantly suppressed by providing an even number of partial loops with equal loop areas and opposite polarities within the Wheatstone bridge circuit of the magnetic sensor 50.

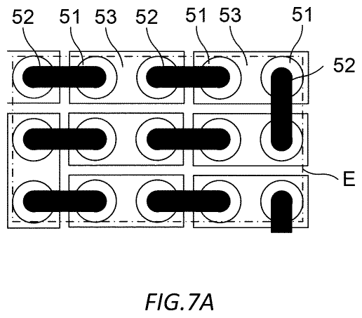

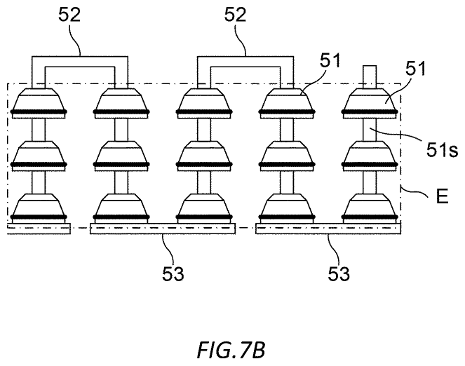

FIG. 7A and FIG. 7B illustrate the arrays of the plurality of magnetoresistive elements 51 in the first magneto-electric conversion unit 50a and the second magneto-electric conversion unit 50b, that is, a planar array and a three-dimensional array, respectively. The resistive sides Ra to Rh include one or more unit regions E in which at least some magnetoresistive elements 51 among the plurality of magnetoresistive elements 51 forming each resistive side are arranged adjacent (tightly) to each other inside. In other words, the plurality of magnetoresistive elements 51 forming one resistive side (for example, the resistive side Ra) are each divided into one or more groups and are arrayed within the unit regions E. It should be noted that the unit regions E may be a planar region or a three-dimensional region.

In the top view illustrated in FIG. 7A, fifteen magnetoresistive elements 51 are arrayed in a 3×5 matrix within a rectangular-shaped planar region E. Herein, the magnetoresistive element 51 positioned at the i-th column (i-th from the top) and j-th row (j-th from the left) is referred to as a magnetoresistive element 51 at (i, j). The upper surfaces of the magnetoresistive elements 51 at (1, 1) and (1, 2), the magnetoresistive elements 51 at (1, 3) and (1, 4), the magnetoresistive elements 51 at (1, 5) and (2, 5), the magnetoresistive elements 51 at (2, 4) and (2, 3), the magnetoresistive elements 51 at (2, 2) and (2, 1), the magnetoresistive elements 51 at (3, 1) and (3, 2), and the magnetoresistive elements 51 at (3, 3) and (3, 4) are each connected via the electrode piece 52. The lower surfaces of the magnetoresistive elements 51 at (1, 2) and (1, 3), the magnetoresistive elements 51 at (1, 4) and (1, 5), the magnetoresistive elements 51 at (2, 5) and (2, 4), the magnetoresistive elements 51 at (2, 3) and (2, 2), the magnetoresistive elements 51 at (2, 1) and (3, 1), the magnetoresistive elements 51 at (3, 2) and (3, 3), and the magnetoresistive elements 51 at (3, 4) and (3, 5) are each connected via the electrode piece 53. In this way, fifteen magnetoresistive elements 51 are arranged within the unit region E to be adjacent to each other by being connected in series such that they make one and half round trip in the lateral direction. The outermost circumference of the fifteen magnetoresistive elements 51 in this case (indicated with the single-dot dash line in the figure) is the unit region E.

In the side view illustrated in FIG. 7B, fifteen magnetoresistive elements 51 constituting one column illustrated in FIG. 7A are arrayed in a 3×5 matrix within a rectangular-shaped three-dimensional region E. In other words, a planar array of three magnetoresistive elements 51 connected in series in the height direction via an electrode rod 51s as illustrated in FIG. 7A allows forty-five magnetoresistive elements 51 connected in series to be arrayed three-dimensionally in a 3×5×3 three-dimensional matrix within a cube-shaped unit region E. The outermost circumference of the forty-five magnetoresistive elements 51 in this case (indicated with the single-dot dash line in the figure) is the unit region E.

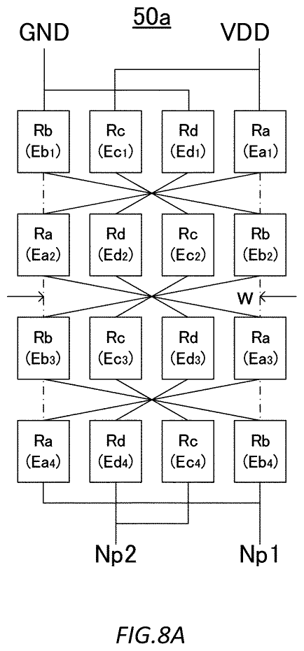

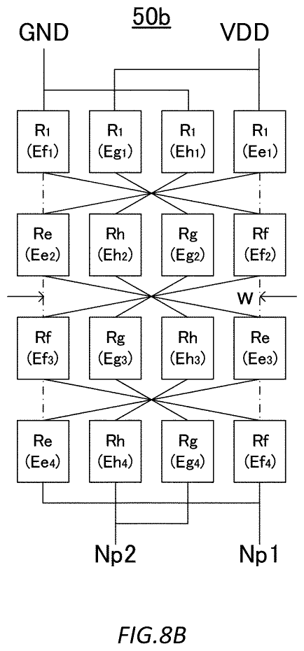

FIG. 8A illustrates an array of the unit regions Ea₁ to Ea₄, Eb₁ to Eb₄, Ec₁ to Ec₄, and Ed₁ to Ed₄ in the first magneto-electric conversion unit 50a. Herein, the up-and-down direction in FIG. 8A corresponds to the up-and-down direction in FIG. 4A and the left-and-right direction in FIG. 8A corresponds to the left-and-right direction in FIG. 4A. Each of the four resistive sides Ra to Rd includes a plurality of (four, as an example) unit regions E and the plurality of magnetoresistive elements 51 forming each resistive side are divided into four groups to be each arrayed within the plurality of unit regions E. It should be noted that the unit regions Ea₁ to Ea₄ included in each resistive side (for example, the resistive side Ra) are hard-wired and all the magnetoresistive elements 51 included in the unit regions Ea₁ to Ea₄ are connected in series.

The unit regions Ea₁ to Ea₄, Eb₁ to Eb₄, Ec₁ to Ec₄, and Ed₁ to Ed₄ of the resistive side Ra to the resistive side Rd, respectively, are arrayed in the width direction of the arm 24c₁ (the left-and-right direction in FIG. 8A). Herein, the resistive side Ra to the resistive side Rd include the unit regions Ea₁ to Ed₁, respectively, and the unit regions Ea₂ to Ed₂, respectively, which are each arranged on one side and the other side (the upper side and the lower side in FIG. 8A) in the conducting direction of the current flowing through the conductor 24 (the arm 24c₁). The unit regions Ea₁ to Ed₁ are arrayed in the order of Eb₁, Ec₁, Ed₁, and Ea₁ from left to right. The unit regions Ea₂ to Ed₂ are arrayed in the reverse order of the unit regions Ea₁ to Ed₁, that is, in the order of Ea₂, Ed₂, Ec₂, and Eb₂ from left to right. In this way, the unit regions Ea₁ to Ed₁ and Ea₂ to Ed₂ included in the resistive side Ra to the resistive side Rd, respectively, are arranged to be 180-degree rotational symmetry in the arm 24c₁. In this way, twisting the connection line of the magnetoresistive element 51 constituting the resistive sides Ra to Rd by reversing the order of the array of the unit regions Ea₁ to Ed₁ and the unit regions Ea₂ to Ed₂ of the resistive sides Ra to Rd can lead to the smaller partial loop formed of the connection line of the magnetoresistive element 51.

It should be noted that the unit regions Ea₁ to Ed₁ and the unit regions Ea₂ to Ed₂ of the resistive side Ra, the resistive side Rb, the resistive side Rc, and the resistive side Rd, respectively, may be arrayed in any order as long as the unit regions Ea₁ to Ed₁ and the unit regions Ea₂ to Ed₂ are arrayed in the reverse order to each other.

Furthermore, the resistive side Ra to the resistive side Rd include the unit regions Ea₃ to Ed₃ and the unit region Ea₄ to Ed₄, respectively, which are arranged on one side and the other side (the upper side and the lower side in FIG. 8A), respectively, in the conducting direction of the current flowing through the conductor 24 (the arm 24c₁). It should be noted that the unit regions Ea₃ to Ed₃ and the unit regions Ea₄ to Ed₄ are arranged below the unit regions Ea₁ to Ed₁ and the unit regions Ea₂ to Ed₂, but the arrangement is not limited thereto and they may be arranged in any position, such as above, to the left, to the right, or diagonally. The unit regions Ea₃ to Ed₃ are arrayed in the order of Eb₃, Ec₃, Ed₃, and Ea₃ from left to right. The unit regions Ea₄ to Ed₄ are arrayed in the reverse order of the unit regions Ea₃ to Ed₃, that is, in the order of Ea₄, Ed₄, Ec₄, and Eb₄ from left to right. In this way, the unit regions Ea₃ to Ed₃ and Ea₄ to Ed₄ included in the resistive side Ra to the resistive side Rd, respectively, are arranged to be 180-degree rotational symmetry in the arm 24c₁. In this way, twisting the connection line of the magnetoresistive element 51 constituting the resistive sides Ra to Rd by reversing the order of the array of the unit regions Ea₃ to Ed₃ and the unit regions Ea₄ to Ed₄ of the resistive sides Ra to Rd can lead to the smaller partial loop formed of the connection line of the magnetoresistive element 51. It should be noted that the array of the unit regions Ea₃ to Ed₃ and the unit regions Ea₄ to Ed₄ does not need to be aligned with the array of the unit regions Ea₁ to Ed₁ and the unit regions Ea₂ to Ed₂, as long as they are in the reverse order to each other.

It should be noted that the unit regions Ea₃ to Ed₃ and the unit regions Ea₄ to Ed₄ of the resistive side Ra, the resistive side Rb, the resistive side Rc, and the resistive side Rd, respectively, may be arrayed in any order as long as the unit regions Ea₃ to Ed₃ and the unit regions Ea₄ to Ed₄ are arrayed in the reverse order to each other.

In this way, providing an even number of partial loops with an equal loop area and opposite polarities within the connection line of the magnetoresistive element 51 included in the resistive side Ra to the resistive side Rd can offset or significantly suppress the di/dt noise.

FIG. 8B illustrates an array of the unit regions Ee₁ to Ee₄, Ef₁ to Ef₄, Eg₁ to Eg₄, and Eh₁ to Eh₄ in the second magneto-electric conversion unit 50b. Herein, the up-and-down direction in FIG. 8B corresponds to the up-and-down direction in FIG. 4A and the left-and-right direction in FIG. 8B corresponds to the left-and-right direction in FIG. 4A. Each of the four resistive sides Re to Rh includes a plurality of (an example, four) unit regions E and the plurality of magnetoresistive elements 51 forming each resistive side are divided into four groups to be each arrayed within the unit region E. It should be noted that the unit regions Re₁ to Re₄ included in each resistive side (for example, resistive side Re) are hard-wired and all the magnetoresistive elements 51 included in the unit regions Re₁ to Re₄ are connected in series.

The unit regions Ee₁ to Ee₄, Ef₁ to Ef₄, Eg₁ to Eg₄, and Eh₁ to Eh₄ of the resistive side Re to the resistive side Rh, respectively, are arrayed in the width direction (the left-and-right direction in FIG. 8B) in the arm 24c₂. Herein, the resistive side Re to the resistive side Rh include the unit regions Ee₁ to Eh₁, respectively, and the unit regions Ee₂ to Eh₂, respectively, which are each arranged on one side and the other side (the upper side and the lower side in FIG. 8B) in the conducting direction of the current flowing through the conductor 24 (the arm 24c₂). The unit regions Ee₁ to Eh₁ are arrayed in the order of Ef₁, Eg₁, Eh₁, Ee₁ from left to right. The unit regions Ee₂ to Eh₂ are arrayed in the reverse order to the unit regions Ee₁ to Eh₁, that is, in the order of Ee₂, Eh₂, Eg₂, Ef₂, from left to right. In this way, the unit regions Ee₁ to Eh₁ and Ee₂ to Eh₂ included in the resistive side Re to the resistive side Rh, respectively, are arranged to be 180-degree rotational symmetry on the arm 24c₂. In this way, twisting the connection line of the magnetoresistive element 51 constituting the resistive sides Re to Rh by reversing the order of the array of the unit regions Ee₁ to Eh₁ and the unit regions Ee₂ to Eh₂ of the resistive sides Re to Rh can lead to the smaller partial loop formed of the connection line of the magnetoresistive element 51.

It should be noted that the unit regions Ee₁ to Eh₁ and the unit regions Ee₂ to Eh₂ of the resistive side Re, the resistive side Rf, the resistive side Rg, and the resistive side Rh, respectively, may be arrayed in any order as long as the unit regions Ee₁ to Eh₁ and the unit regions Ee₂ to Eh₂ are arrayed in the reverse order to each other.

Furthermore, the resistive side Re to the resistive side Rh include the unit regions Ee₃ to Eh₃ and the unit regions Ee₄ to Eh₄, respectively, which are arranged on one side and the other side (the upper side and the lower side in FIG. 8B), respectively, in the conducting direction of the current flowing through the conductor 24 (the arm 24c₂). It should be noted that the unit regions Ee₃ to Eh₃ and the unit regions Ee₄ to Eh₄ are arranged below the unit regions Ee₃ to Eh₃ and the unit regions Ee₄ to Eh₄, but the arrangement is not limited thereto and they may be arranged in any position, such as above, to the left, to the right, or diagonally. The unit regions Ee₃ to Eh₃ are arrayed in the order of Ef₃, Eg₃, Eh₃, and Ee₃ from left to right. The unit regions Ee₄ to Eh₄ are arrayed in the reverse order of the unit regions Ee₃ to Eh₃, that is, in the order of Ee₄, Eh₄, Eg₄, and Ef₄, from left to right. In this way, the unit regions Ee₃ to Eh₃ and Ee₄ to Eh₄ included in the resistive side Re to the resistive side Rh, respectively, are arranged to be 180-degree rotational symmetry on the arm 24c₂. In this way, twisting the connection line of the magnetoresistive element 51 constituting the resistive sides Re to Rh by reversing the order of the array of the unit regions Ee₃ to Eh₃ and the unit regions Ee₄ to Eh₄ of the resistive sides Re to Rh can lead to the smaller partial loop formed of the connection line of the magnetoresistive element 51. It should be noted that the array of the unit regions Ee₃ to Eh₃ and the unit regions Ee₄ to Eh₄ does not need to be aligned with the array of the unit regions Ee₁ to Eh₁ and the unit regions Ee₂ to Eh₂ as long as they are in the reverse order to each other.

It should be noted that the unit regions Ee₃ to Eh₃ and the unit regions Ee₄ to Eh₄ of the resistive side Re, the resistive side Rf, the resistive side Rg, and the resistive side Rh, respectively, may be arrayed in any order as long as the unit regions Ee₃ to Eh₃ and the unit regions Ee₄ to Eh₄ are arrayed in the reverse order to each other.

In this way, providing an even number of partial loops with an equal loop area and opposite polarities within the connection line of the magnetoresistive element 51 included in the resistive side Re to the resistive side Rh can offset or significantly suppress the di/dt noise. On the other hand, the intensity distribution of the magnetic field may result in the difference in the amount of magnetic sensitivity between the plurality of partial loops to generate a common mode voltage.

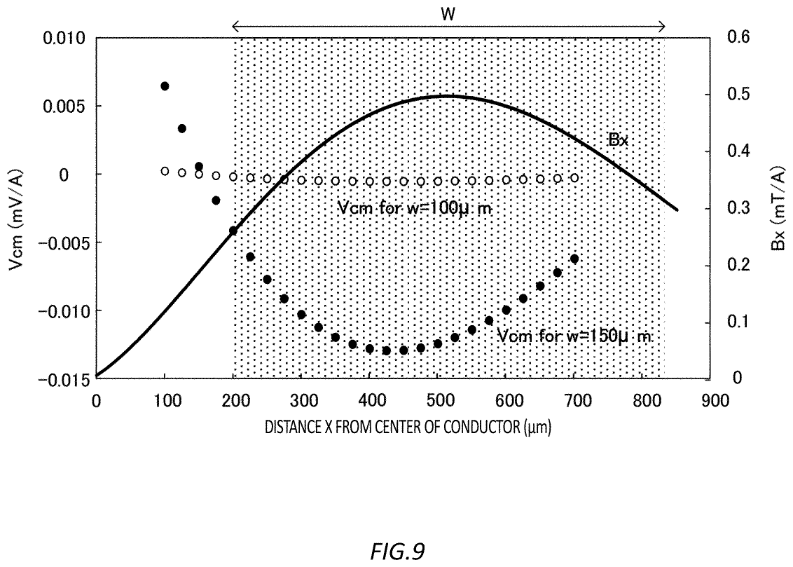

FIG. 9 illustrates the magnetic field intensity and the common mode voltage Vcm that is output from the first magneto-electric conversion unit 50a relative to the position X on the arm 24c₁ of the conductor 24. The position X on the arm 24c₁ is defined with respect to the gap center line L on the conductor 24 as the reference (see FIG. 4A). The common mode voltage Vcm of the first magneto-electric conversion unit 50a is defined as the average of the voltage that is output from each of the output terminals Np1, Np2 when the center of the first magneto-electric conversion unit 50a (the center of the 4×4 unit region in FIG. 8A) is positioned at a distance X from the gap center line L. The width W of the arm 24c₁ is 620 μm, as an example, and the position X on the arm 24c₁ is indicated with hatching. The width w of the first magneto-electric conversion unit 50a can be defined as a separation distance between the center of gravity (which may be the plane center) of the unit region of the resistive sides Ra to Rd positioned on one outermost side in the width direction of the arm 24c₁ (for example, the unit region Eb₁ positioned to the leftmost in the first row in FIG. 8A) and the center of gravity (which may be the plane center) of the unit region of the resistive sides Ra to Rd positioned on the other outermost side (the unit region Ea₁ positioned on the rightmost in the first row in FIG. 8A).

Herein, in FIG. 8A, since each magnetoresistive element is arranged in alignment in a 4×4 rectangular pattern, the center of the first magneto-electric conversion unit 50a is defined as the center of the rectangle. On the other hand, each magnetoresistive element does not necessarily need to be arranged in alignment in a rectangular pattern. In this case, the center of the first magneto-electric conversion unit 50a may be defined as the center of the square with the smallest area among the squares that surround all the centers of gravity of the magnetoresistive elements constituting the first resistive side to the fourth resistive side in the planar view and two sides of which are parallel to the width direction and two sides of which are perpendicular to the width direction.

When the unit current flows through the conductor 24, the magnetic field Bx parallel to the width direction of the upper surface of the arm 24c₁ is generated. The parallel magnetic field Bx has an intensity profile in which it is weakest at the gap center line L with respect to the width direction (identical to the X axis direction), increases as it moves away from the gap center line L in the +X direction, is strongest at the position somewhat closer to the origin relative to the center line of the arm 24c₁, and decreases as it moves further away from the gap center line L in the +X direction. In contrast, if the width w of the first magneto-electric conversion unit 50a is 150 μm, the common mode voltage Vcm output from the first magneto-electric conversion unit 50a has a profile in which it has a positive value when the center of the first magneto-electric conversion unit 50a is positioned within a gap, is zero on the extremely inner side of the arm 24c₁ (around 150 μm from the gap center line L), increases toward the negative direction as it moves away from the gap center line L in the +X direction, and is local minimum at the position somewhat closer to the gap center line L relative to the position of the maximum parallel magnetic field Bx, and increases toward the positive direction as it moves further away from the gap center line L in the +X direction. If the width w of the first magneto-electric conversion unit 50a is 100 μm, the common mode voltage Vcm output from the first magneto-electric conversion unit 50a has a profile similar to the case in which the width w=150 μm and has an extremely small absolute value relative to the case in which the width w=150 μm.

Therefore, the center of the first magneto-electric conversion unit 50a (the resistive side Ra to resistive side Rd) is preferably positioned on a side of the gap center line L (that is, the arm 24c₂) with respect to the width direction relative to the position of the maximum parallel magnetic field Bx generated on the arm 24c₁ when the current flows through the conductor 24. In this way, the parallel magnetic field Bx becomes smaller and the common mode voltage Vcm can be suppressed. In addition, the center of the first magneto-electric conversion unit 50a (the resistive side Ra to the resistive side Rd) is preferably positioned on a side of the arm 24c₂ relative to the center line of the arm 24c₁ with respect to the width direction. In this way, the magnetic sensor 50 that includes the first magneto-electric conversion unit 50a and the second magneto-electric conversion unit 50b can be configured in a compact manner.

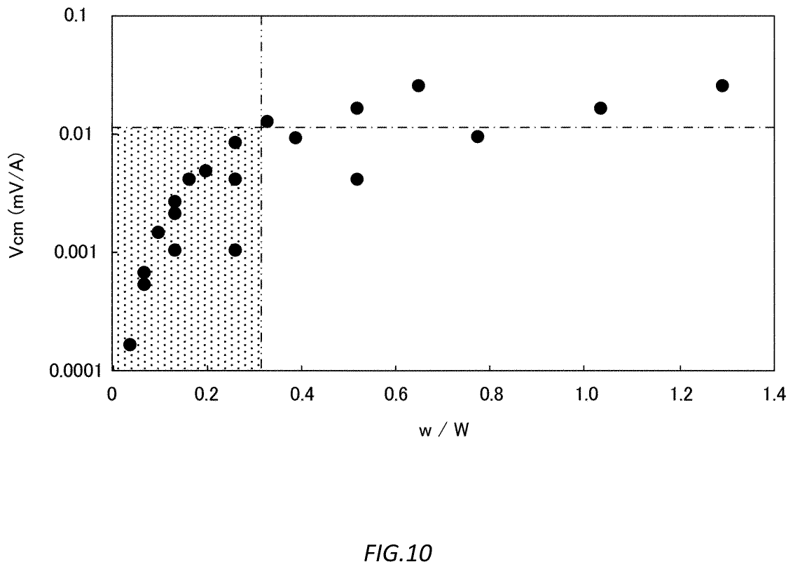

FIG. 10 illustrates the common mode voltage Vcm output from the first magneto-electric conversion unit 50a relative to the ratio of the width w of the first magneto-electric conversion unit 50a to the width W of the arm 24c₁. It should be noted that the center of the first magneto-electric conversion unit 50a can be arranged at any position on the upper surface of the arm 24c₁ and in particular can be arranged on the center line of the arm 24c₁ where the common mode voltage Vcm may be maximum. The common mode voltage Vcm of the first magneto-electric conversion unit 50a is the average of the voltage output from each of the output terminals Np1, Np2 when the unit current flows through the conductor 24. The common mode voltage Vcm increases as the ratio w/W increases and exceeds 0.01 mV/A, which is the specification limit, when the ratio is about 0.3 or more. Therefore, the width w of the first magneto-electric conversion unit 50a is preferably small relative to the width W of the arm 24c₁ and can suppress the common mode voltage Vcm to the specification limit or less especially when it is 0.3 times or less the width W of the arm 24c₁. It should be noted that the width w of the first magneto-electric conversion unit 50a may be 0.27 times or less, preferably 0.25 times or less, more preferably 0.23 times or less, or even more preferably 0.20 times or less the width W of the arm 24c₁.

The manufacturing method of the current sensor 100 will be described.

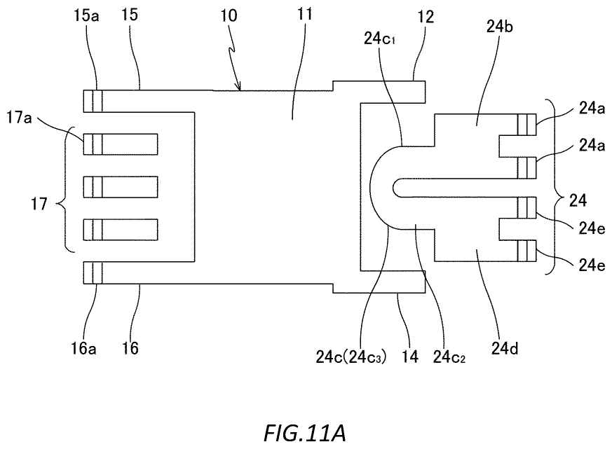

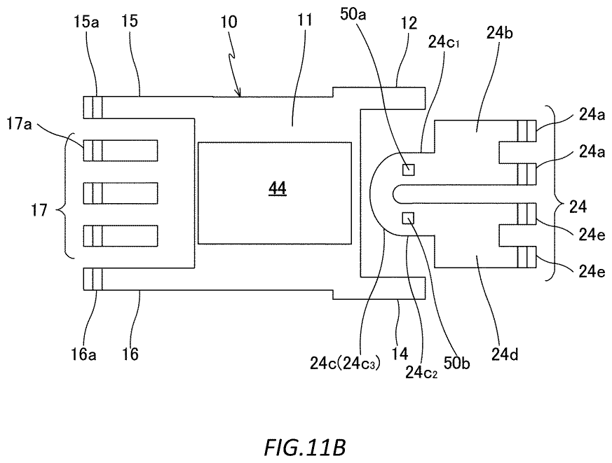

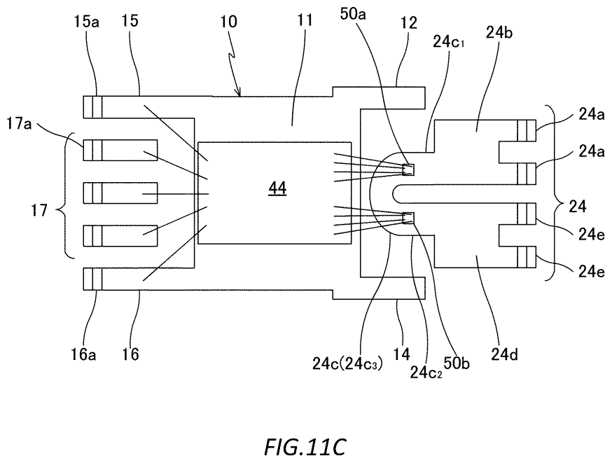

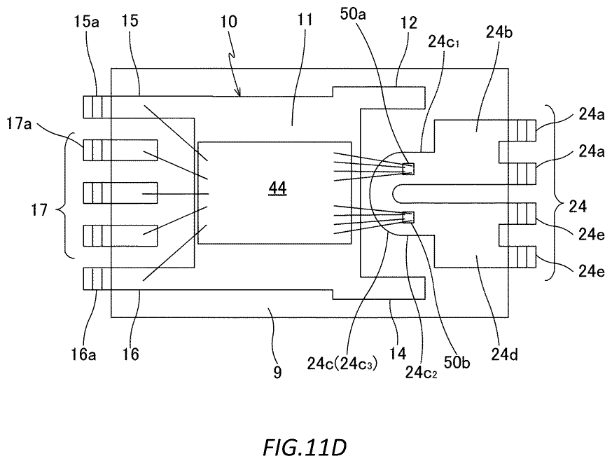

As illustrated in FIG. 11A, at first, one metal board undergoes the stamping process to form the pattern of the base 10, the plurality of device terminals 17, and the conductor 24. This pattern allows the base 10, the plurality of device terminals 17, and the conductor 24 to be included within a rectangular-shaped frame (not shown), with their terminal portions coupled inside.

Then, the pattern undergoes a step process to provide steps in the device terminals 15, 16 of the base 10, the plurality of device terminals 17, and the conductor 24. As a result, the inner parts of the pattern are raised relative to the frame and their terminal portions coupled to the frame.

As illustrated in FIG. 11B, the magnetic sensor 50 (the first magneto-electric conversion unit 50a and the second magneto-electric conversion unit 50b) and the signal processing device 44 are then installed. Herein, the first magneto-electric conversion unit 50a and the second magneto-electric conversion unit 50b are arranged on the arms 24c₁, 24c₂ of the conductor 24, respectively. The signal processing device 44 is arranged on the body 11 of the base 10.

As illustrated in FIG. 11C, the magnetic sensor 50 (the first magneto-electric conversion unit 50a and the second magneto-electric conversion unit 50b) is then connected to the signal processing device 44 and the signal processing device 44 is connected to the device terminals 15, 16, 17, both via wire bonding.

As illustrated in FIG. 11D, the pattern is then molded such that the frame as well as the base 10, the plurality of device terminals 17, and the terminal portion of the conductor 24 coupled to the frame are left. As a result, a package 9 is formed, and encapsulates therein the magnetic sensor 50, the signal processing device 44, and the inner part of the pattern on which these are installed.

Finally, the frame exposed on the outside of the package 9 is cut off from the pattern. In this way, the base 10, the plurality of device terminal 17, and the conductor 24 are separated from each other to complete the current sensor 100.

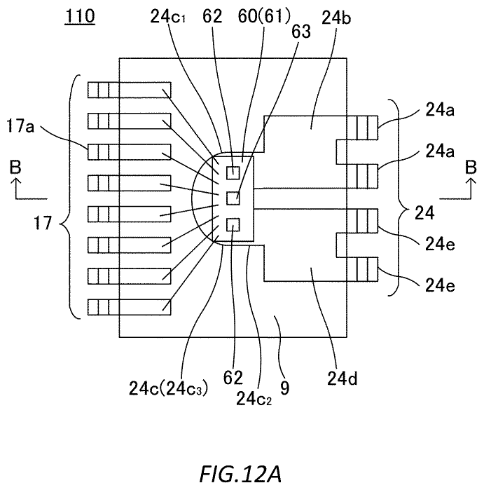

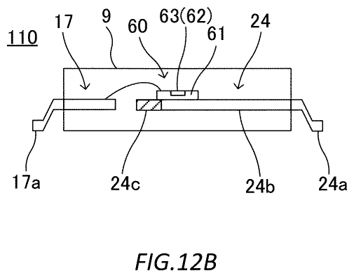

FIG. 12A and FIG. 12B illustrate the internal configuration of the current sensor 110 according to a modified example in a top view and a side view, respectively, omitting the package 9. Herein, FIG. 12B illustrates the cross-sectional structure of the current sensor 110 with respect to the reference line BB in FIG. 12A. It should be noted that an up-and-down direction in FIG. 12A is referred to as a longitudinal direction, a left-and-right direction in FIG. 12A and FIG. 12B is referred to as a lateral direction, and an up-and-down direction in FIG. 12B is referred to as a height direction. The current sensor 110 is a sensor for measuring the amount of currents by detecting, using a magnetic sensor 60, the magnetic field generated around the conductor 24 through which a to-be-measured current flows, and in particular can suppress di/dt noise due to an induced electromotive force and/or a differential amplification noise resulting from the spread of magnetic field distribution. The current sensor 110 includes the package 9, the plurality of device terminals 17, the conductor 24, and the magnetic sensor 60.

The package 9 is a member that protects each unit constituting the current sensor 110 by encapsulating it inside, except for the plurality of device terminals 17 and each terminal portion of the conductor 24. The package 9 can be formed of a material similar to that of the package 9 for the current sensor 100 according to the first embodiment.

The plurality of device terminals 17 are secondary conductors for outputting, to an external device, a detection result of the to-be-measured current outputted from the magnetic sensor 60. In the present example, as an example, eight device terminals 17 are arrayed at regular intervals on a left side of the package 9 with their longitudinal sides being oriented in the lateral direction. The plurality of device terminals 17 are formed similarly to those for the current sensor 100 according to the first embodiment.

The conductor 24 is a primary conductor that forms a current path in which the to-be-measured current is flowing. The conductor 24 is formed similarly to that for the current sensor 100 according to the first embodiment, with its terminal portions 24a, 24e being arranged on the right side of the package 9 and the two arms 24c₁, 24c₂, which are included in the curved portion 24c, being arranged at the center of the package 9.

The magnetic sensor 60 is a sensor which detects a magnetic field generated by the to-be-measured current flowing through the conductor 24. As an example, the magnetic sensor 60 is configured to detect the magnetic field in the longitudinal direction generated around the conductor 24 (an example of the horizontal magnetic field) and includes the substrate 61, the two magneto-electric conversion units 62, and the signal processing device 63.

The substrate 61 is a board-like member supporting the two magneto-electric conversion units 62. The substrate 61 is formed of, for example, silicon (Si), and has a plurality of wiring lines (not shown) laid on its upper surface.

The two magneto-electric conversion units 62 detect the magnetic field generated by the to-be-measured current flowing through the conductor 24. The two magneto-electric conversion units 62 include four resistive sides that are made of the magnetoresistive elements 51 arrayed on the substrate 61 and are connected in a Wheatstone bridge circuit similarly to the first magneto-electric conversion unit 50a and the second magneto-electric conversion unit 50b as described above. The two magneto-electric conversion units 62 are arranged on the substrate 61 such that they are separated in the longitudinal direction (the width direction of the arms 24c₁, 24c₂), and each power supply terminal VDD, ground terminal GND, and output terminals Np1, Np2 are connected to the signal processing device 63 via the wiring line on the substrate 61.

The signal processing device 63 is a device that processes the output signal of the two magneto-electric conversion units 62 and calculates the amount of the to-be-measured current flowing through the conductor 24. The signal processing device 63 can be configured similarly to the signal processing device 44 as described above. The signal processing device 63 is formed monolithically together with the two magneto-electric conversion units 62 on the substrate 61 and, in the present example, is arranged at the center of the substrate 61, and is connected to the device terminal 17 via the wiring line (not shown) laid on the substrate 61 and the wire bonding. In this way, the signal processing device 63 can output, via the device terminal 17, the calculation result of the amount of the to-be-measured current flowing through the conductor 24.

The magnetic sensor 60 is arranged on the curved portion 24c of the conductor 24. In this way, the two magneto-electric conversion units 62 are each arranged on the two arms 24c₁, 24c₂ of the curved portion 24c. In this way, the drive voltage can be applied to the two magneto-electric conversion units 62 via the device terminal 17 while outputting the amount of the to-be-measured current calculated by the signal processing device 63 based on each output voltage.

The manufacturing method of the current sensor 110 according to the modified example is described.

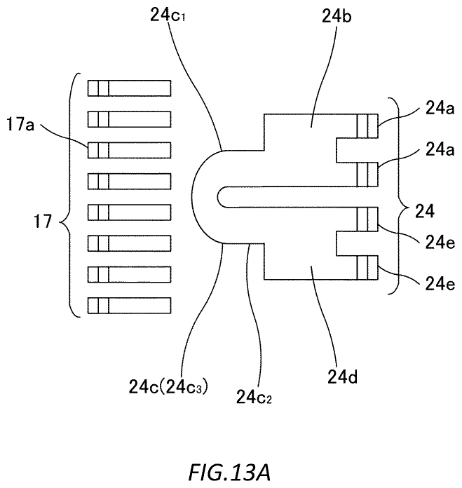

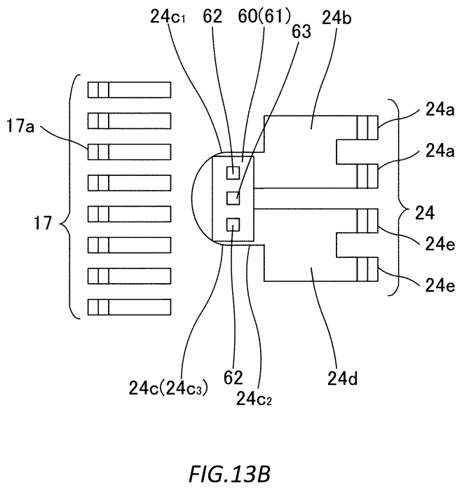

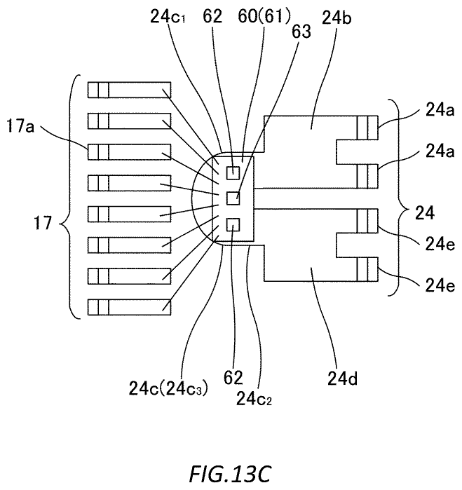

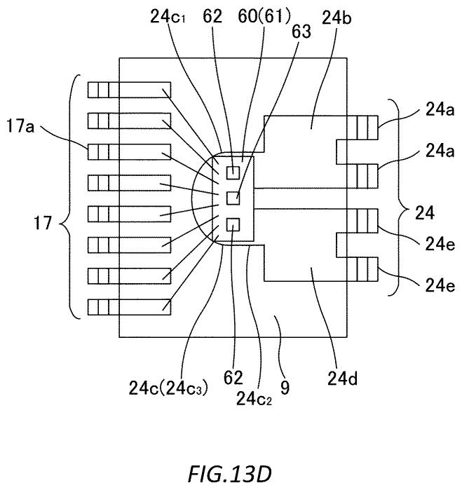

As illustrated in FIG. 13A, at first, one piece of metal board undergoes a stamping process to form the pattern of the plurality of device terminals 17 and the conductor 24. This pattern allows the plurality of device terminals 17 and the conductor 24 to be included within a rectangular-shaped frame (not shown), with their terminal portions coupled inside.

Then, the pattern undergoes a step process to provide steps in the plurality of device terminals 17 and the conductor 24. In this way, the terminal portions 17a are formed on the plurality of device terminals 17 and the terminal portions 24a, 24e are formed on the conductor 24, and the inner part of the pattern is raised relative to these terminal portions.

As illustrated in FIG. 13B, the magnetic sensor 60 is then installed on the curved portion 24c of the conductor 24. Herein, the two magneto-electric conversion units 62 are each arranged on the arms 24c₁, 24c₂ of the conductor 24.

As illustrated in FIG. 13C, the magnetic sensor 60 is then connected to the plurality of device terminals 17 via wire bonding.

As illustrated in FIG. 13D, the pattern is then molded such that the frame as well as the plurality of device terminals 17, the terminal portion 17a, and the terminal portions 24a, 24e of the conductor 24 coupled to the frame are left, to form the package 9. In this way, the package 9 is formed and the magnetic sensor 60 and the inner part of the pattern are encapsulated inside the package 9.

Finally, the frame exposed on the outside of the package 9 is cut off from the pattern. In this way, the plurality of device terminals 17 and the conductor 24 are separated from each other to complete the current sensor 110.

It should be noted that the magnetic sensor 60 may not include the signal processing device 63 and the wiring line on the substrate 61 connected to the power supply terminal VDD, the ground terminal GND, and the output terminals Np1, Np2 of the two magneto-electric conversion units 62 may be connected to the device terminal 17 via wire bonding. In this way, the drive voltage can be applied to the two magneto-electric conversion units 62 via the device terminal 17 while outputting each output voltage.

The magnetic sensor 50 according to the present embodiment includes a first magneto-electric conversion unit 50a including the resistive side Ra, the resistive side Rb, the resistive side Rc, and the resistive side Rd, each formed by connecting the plurality of magnetoresistive elements 51 in series, wherein the magnetic sensing directions of the resistive side Ra and the resistive side Rd are identical to each other, the magnetic sensing directions of the resistive side Rb and the resistive side Rc are identical to each other and opposite to the magnetic sensing direction of the resistive side Ra and the resistive side Rd, the resistive side Ra and the resistive side Rb are connected in series, the resistive side Rc and the resistive side Rd are connected in series and are connected in parallel to the resistive side Ra and the resistive side Rb to be assembled into the Wheatstone bridge circuit, and at least a part the first magneto-electric conversion unit 50a is arranged on the arm 24c₁ included in the conductor 24, wherein the width w of the first magneto-electric conversion unit 50a, which is the separation distance between the center of gravity of the unit region E of the resistive sides Ra to Rd positioned on one outermost side in the width direction of the arm 24c₁ of the conductor 24 and the center of gravity of the unit region E of the resistive sides Ra to Rd positioned at the other outermost side is 0.3 times or less the width W of the arm 24c₁, the unit region E being among the unit regions E where at least some magnetoresistive elements 51 among the plurality of magnetoresistive elements 51 each forming the resistive side Ra to the resistive side Rd are arranged to be adjacent in the width direction. When the width w of the first magneto-electric conversion unit 50a is 0.3 times or less the width of the arm 24c₁ of the conductor 24, the imbalance in each magnetic sensitivity of the resistive side Ra to the resistive side Rd due to the magnetic field distribution on the arm 24c₁ with respect to the width direction of the arm 24c₁ is small, which can suppress the common mode voltage Vcm included in the output voltage output from the connection point of the resistive side Ra and the resistive side Rb and the connection point of the resistive side Rc and the resistive side Rd.

In addition, the current sensor 100 according to the present embodiment includes the conductor 24 through which the to-be-measured current flows and the magnetic sensor 50. According to this, the di/dt noise due to the induced electromotive force and/or the differential amplification noise due to the spread of the magnetic field distribution can be suppressed.

It should be noted that the conductor 24 through which the to-be-measured current flows includes the arm 24c₁, the arm 24c₂ separated from the arm 24c₁ in the width direction, and the joining portion 24c₃ joining the arm 24c₁ and the arm 24c₂, and the arm 24c₁ and the arm 24c₂ extend on the same side with respect to the joining portion 24c₃. Herein, the distance from the surface on the side of the conductor 24 including the magneto-electric conversion unit 50a to the magneto-sensitive surface of the magnetoresistive element 51 (that is, the height of the magneto-sensitive surface of the magnetoresistive element 51 from the surface of the conductor 24) may be greater than 0.16 mm and may be 3.5 mm or less. According to this, the suppression of the di/dt noise due to the induced electromotive force and/or the differential amplification noise due to the spread of the magnetic field distribution and the sensitivity of the magnetoresistive element can be balanced.

While the present invention has been described by way of the embodiments, the technical scope of the present invention is not limited to the scope described in the above-described embodiments. It is apparent to persons skilled in the art that various modifications or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “then” for the sake of convenience in the claims, specification, or drawings, it does not necessarily mean that the process must be performed in this order.

What is claimed is:

1. A magnetic sensor comprising a first magneto-electric conversion unit including a first resistive side, a second resistive side, a third resistive side, and a fourth resistive side, each formed by connecting a plurality of magnetoresistive elements in series, wherein magnetic sensing directions of the first resistive side and the fourth resistive side are identical to each other and magnetic sensing directions of the second resistive side and the third resistive side are identical to each other and opposite to the magnetic sensing directions of the first resistive side and the fourth resistive side, the first resistive side and the second resistive side are connected in series, the third resistive side and the fourth resistive side are connected in series and are connected in parallel to the first resistive side and the second resistive side to be assembled into a Wheatstone bridge circuit, and at least a part of the first magneto-electric conversion unit is arranged on a first arm included in a conductor,
wherein a width of the first magneto-electric conversion unit, which is a separation distance between a center of gravity of a unit region of a resistive side positioned on one outermost side in a width direction of the first arm and a center of gravity of a unit region of a resistive side positioned at another outermost side is 0.3 times or less a width of the first arm, the unit region being among unit regions where at least some magnetoresistive elements among the plurality of magnetoresistive elements each forming the first resistive side to the fourth resistive side are arranged to be adjacent in a width direction.

2. The magnetic sensor according to claim 1, wherein the conductor further includes a second arm that is separated from the first arm in the width direction, wherein a current is input to one arm among the first arm and the second arm and the current is output from another arm, and
the first magneto-electric conversion unit including the first resistive side to the fourth resistive side is positioned on a side of the second arm relative to a center line of the first arm with respect to the width direction.

3. The magnetic sensor according to claim 1, wherein the conductor further includes a second arm that is separated from the first arm in the width direction, wherein a current is input into one arm among the first arm and the second arm and the current is output from another arm,
wherein a center of the first magneto-electric conversion unit including the first resistive side to the fourth resistive side is positioned on a side of the second arm relative to a position of a maximum magnetic field generated on the first arm when the current flows through the conductor, with respect to the width direction.

4. The magnetic sensor according to claim 1, wherein a unit region of each of the first resistive side to the fourth resistive side is arrayed in the width direction.

5. The magnetic sensor according to claim 4, wherein each of the first resistive side to the fourth resistive side includes a first unit region and a second unit region, each arranged on one side and another side in a conducting direction of a current flowing through the conductor,
the first unit region of each of the first resistive side to the fourth resistive side is arrayed in the width direction, and
the second unit region of each of the first resistive side to the fourth resistive side is arrayed in a reverse order to the first unit region in the width direction.

6. The magnetic sensor according to claim 5, wherein each of the first resistive side to the fourth resistive side further includes a third unit region and a fourth unit region each arranged on one side and another side in the conducting direction of the current,
the third unit region of each of the first resistive side to the fourth resistive side is arrayed in the width direction, and
the fourth unit region of each of the first resistive side to the fourth resistive side is arrayed in a reverse order to the third unit region in the width direction.

7. The magnetic sensor according to claim 5, wherein the first unit region and the second unit region included in each of the first resistive side to the fourth resistive side are arranged to have 180-degree rotational symmetry on the first arm.

8. The magnetic sensor according to claim 1, wherein the at least some magnetoresistive elements are arrayed three-dimensionally within the unit region.

9. The magnetic sensor according to claim 1, wherein the plurality of magnetoresistive elements are tunneling magnetoresistive elements or giant magnetoresistive elements.

10. The magnetic sensor according to claim 1, wherein the magnetic sensing direction of the first resistive side to the fourth resistive side is parallel to the width direction.

11. The magnetic sensor according to claim 2, further comprising a second magneto-electric conversion unit including a fifth resistive side, a sixth resistive side, a seventh resistive side, and an eighth resistive side, each formed by connecting a plurality of magnetoresistive elements in series, wherein magnetic sensing directions of the fifth resistive side and the eighth resistive side are identical to each other, magnetic sensing directions of the sixth resistive side and the seventh resistive side are identical to each other and opposite to magnetic sensing directions of the fifth resistive side and the eighth resistive side, the fifth resistive side and the sixth resistive side are connected in series, the seventh resistive side and the eighth resistive side are connected in series and are connected in parallel to the fifth resistive side and the sixth resistive side to be assembled into a Wheatstone bridge circuit, and at least a part of the second magneto-electric conversion unit is arranged on the second arm and is connected in parallel to the first magneto-electric conversion unit.

12. The magnetic sensor according to claim 11, wherein a unit region where at least some magnetoresistive elements among a plurality of magnetoresistive elements each forming the fifth resistive side, the sixth resistive side, the seventh resistive side, and the eighth resistive side are arranged to be adjacent is arrayed in the width direction.

13. The magnetic sensor according to claim 12, wherein each of the fifth resistive side to the eighth resistive side includes a fifth unit region and a sixth unit region each arranged on one side and another side of the conducting direction of the current,
the fifth unit region of each of the fifth resistive side to the eighth resistive side is arrayed in the width direction, and
the sixth unit region of each of the fifth resistive side to the eighth resistive side is arrayed in a reverse order of the fifth unit region in the width direction.

14. The magnetic sensor according to claim 13, wherein each of the fifth resistive side to the eighth resistive side further includes a seventh unit region and an eighth unit region each arranged on one side and another side of the conducting direction of the current,
the seventh unit region of each of the fifth resistive side to the eighth resistive side is arrayed in the width direction, and
the eighth unit region of each of the fifth resistive side to the eighth resistive side is arrayed in a reverse order of the seventh unit region in the width direction.

15. A current sensor comprising:
the magnetic sensor according to any one of claims 1 to 14; and
the conductor through which a to-be-measured current flows.

16. The current sensor according to claim 15, wherein the conductor through which the to-be-measured current flows includes a first arm, a second arm separated from the first arm in the width direction, and a joining portion joining the first arm and the second arm, and
the first arm and the second arm extend on a same side with respect to the joining portion.

17. The current sensor according to claim 15, wherein a distance from a surface on a side of the conductor including a magneto-electric conversion unit to a magneto-sensitive surface is greater than 0.16 mm.
